(19) United States
(12) Patent Application Publication
(10) Pub. No.: US 2026/0168131 A1
(43) Pub. Date: Jun. 18, 2026

(54) PRODUCTION METHOD OF MONOCRYSTALLINE SILICON FOR EPITAXIAL SILICON WAFER AND PRODUCTION METHOD OF EPITAXIAL SILICON WAFER

(71) Applicant: SUMCO CORPORATION, Tokyo (JP)

(72) Inventors: Yasuhito NARUSHIMA, Nagasaki (JP); Koichi MAEGAWA, Nagasaki (JP); Fukuo OGAWA, Nagasaki (JP); Yasufumi KAWAKAMI, Nagasaki (JP)

(73) Assignee: SUMCO CORPORATION, Tokyo (JP)

(21) Appl. No.: 19/536,968

(22) Filed: Feb. 11, 2026

Related U.S. Application Data
(63) Continuation of application No. 16/606,931, now abandoned.

(30) Foreign Application Priority Data
Apr. 25, 2017 (JP) 2017-086529

(51) Int. Cl. C30B 15/20; C30B 15/04; C30B 15/14; C30B 25/20; C30B 29/06; H10P 14/20; H10P 95/90

(52) U.S. Cl. CPC C30B 15/206; C30B 15/04; C30B 15/14; C30B 25/20; C30B 29/06; H10P 14/3458; H10P 95/90

(57) ABSTRACT

A production method of a monocrystalline silicon includes adding red phosphorus in a silicon melt so that an electrical resistivity of the monocrystalline silicon falls in a range of 0.5 mΩ·cm or more and less than 0.7 mΩ·cm; and pulling up the monocrystalline silicon so that a time for a temperature of at least a part of a straight body of the monocrystalline silicon to be within a range of 570° C.±70° C. is in a range from 10 minutes to 50 minutes.

This is a Continuation of U.S. application Ser. No. 16/606,931, filed Oct. 21, 2019, which is the U.S. National Stage of PCT/JP2018/015381, filed Apr. 12, 2018, which claims priority to JP Application No. 2017-086529, filed Apr. 25, 2017. The disclosure of each of these applications is herein incorporated by reference in its entirety.

### TECHNICAL FIELD

The present invention relates to a production method of a monocrystalline silicon, a production method of an epitaxial silicon wafer, a monocrystalline silicon, and an epitaxial silicon wafer.

### BACKGROUND ART

It is demanded for an epitaxial silicon wafer for, for instance, a power MOS (Metal Oxide Semiconductor) to exhibit extremely low electrical resistivity. In order to meet the above demand, a production method of an epitaxial silicon wafer including a silicon wafer doped with a high concentration of n-type dopant in a form of phosphorus (P) and an epitaxial film has been studied (see, for instance, Patent Literature 1).

In the production method disclosed in Patent Literature 1, a monocrystalline silicon containing red phosphorus is produced so that electrical resistivity of the monocrystalline silicon falls in a range from 0.7 mΩ·cm to 0.9 mΩ·cm. In producing the monocrystalline silicon, the monocrystalline silicon is pulled up so that a time for the temperature of the monocrystalline silicon to be 570 degrees C.±70 degrees C. falls in a range from 20 minutes to 200 minutes.

By forming an epitaxial film on the silicon wafer obtained from the monocrystalline silicon, developments of micropits in the silicon wafer and stacking faults (abbreviated as SF hereinafter) derived from the micropits are reduced. Consequently, the density of LPD (Light Point Defect) of 90 nm or more becomes 0.1 per square centimeters or less, so that a high-quality epitaxial silicon wafer with low electrical resistivity can be obtained.

### CITATION LIST

### Patent Literature(S)

Patent Literature 1 Japanese Patent No. 5890587

### SUMMARY OF THE INVENTION

### Problem(s) to be Solved by the Invention

There arises a need for an n-type silicon wafer with less than 0.7 mΩ·cm electrical resistivity in these days. In order to meet the need, the method disclosed in Patent Literature 1 may be tried.

However, with the extremely low electrical resistivity as described above, the method disclosed in Patent Literature 1 is not capable of reducing the development of SF, failing to produce a high-quality epitaxial silicon wafer.

An object of the invention is to provide a production method of a monocrystalline silicon, a production method of an epitaxial silicon wafer, and a monocrystalline silicon that are capable of producing a high-quality epitaxial silicon wafer with low electrical resistivity, and to provide a high-quality epitaxial silicon wafer with low electrical resistivity.

### Means for Solving the Problem(s)

A production method of a monocrystalline silicon according to an aspect of the invention uses a monocrystal pull-up apparatus, the apparatus including: a chamber; a crucible disposed inside the chamber and configured to receive a dopant-added melt comprising a silicon melt and red phosphorus added to the silicon melt; and a pull-up unit configured to pull up a seed crystal after bringing the seed crystal into contact with the dopant-added melt. The production method includes: adding the red phosphorus in the silicon melt so that an electrical resistivity of the monocrystalline silicon falls in a range of 0.5 mΩ·cm or more and less than 0.7 mΩ·cm; and pulling up the monocrystalline silicon so that a time for a temperature of at least a part of a straight body of the monocrystalline silicon to be 570 degrees C.±70 degrees C. is in a range from 10 minutes to 50 minutes.

When the time for a temperature of at least a part of the straight body of the monocrystalline silicon to be 570 degrees C.±70 degrees C. (sometimes referred to as a residence time in the range of 570 degrees C.±70 degrees C.) exceeds 50 minutes, a large number of SF develops unlike a monocrystalline silicon whose electrical resistivity is 0.7 mΩ·cm or more. Meanwhile, when the residence time is less than 10 minutes, the monocrystalline silicon may be cracked due to thermal shock.

According to the above aspect of the invention, the density of micropits, which are the cause of development of SF, can be reduced to 2.5 per square centimeters when a silicon wafer obtained from at least a part of the monocrystalline silicon is subjected to a heat treatment (heating in a hydrogen atmosphere at 1200 degrees C. for 30 seconds) similar to a hydrogen baking step before an epitaxial film is formed. Accordingly, an epitaxial silicon wafer produced from the above-described monocrystalline silicon exhibits a density of 90 nm or more LPD of 2.5 per square centimeters or less as measured by SP-1 manufactured by KLA-Tencor Corporation in DCN mode. Thus, a high-quality epitaxial silicon wafer with low electrical resistivity can be obtained.

Germanium (Ge) may be added to the silicon melt as well as red phosphorus. With the above arrangement, the development of dislocation defects (misfit dislocations) caused due to concentration difference of red phosphorus at an interface between the silicon wafer and the epitaxial film can be further reduced.

A production method of a monocrystalline silicon according to another aspect of the invention uses a monocrystal pull-up apparatus, the apparatus including: a crucible disposed inside the chamber and configured to receive a dopant-added melt comprising a silicon melt and red phosphorus added to the silicon melt; a heating unit configured to heat the crucible; and a pull-up unit configured to pull up a seed crystal after bringing the seed crystal into contact with the dopant-added melt. The production method includes: a monocrystal-formation step in which the red phosphorus is added to the silicon melt so that an electrical resistivity of the monocrystalline silicon falls in a range of 0.5 mΩ·cm or more and less than 0.7 mΩ·cm, and the monocrystalline silicon is pulled up; and a cooling step for cooling the monocrystalline silicon. In the cooling step, the monocrystalline silicon is pulled up by 400 mm or more within 180 minutes from separating the monocrystalline silicon from the dopant-added melt.

According to the above aspect of the invention, the residence time for a temperature of at least a part of the straight body of the monocrystalline silicon to be 570 degrees C.±70 degrees C. can be set to be in a range from 10 minutes to 50 minutes. When a silicon wafer obtained from at least the part of the straight body of the monocrystalline silicon is subjected to a heat treatment similar to that in the hydrogen baking step, the density of micropits, which are the cause of development of SF, can be reduced to 2.5 per square centimeters or less. Thus, a high-quality epitaxial silicon wafer with low electrical resistivity can be obtained.

Also in the above aspect of the invention, germanium may be added to the silicon melt as well as red phosphorus.

In the above aspect of the invention, it is preferable that, in the cooling step, the monocrystalline silicon is pulled up with a power of the heating unit being half or less of the power of the heating unit immediately before starting the cooling step. It is especially preferable that the power of the heating unit is reduced to 0%.

According to the above arrangement, the heat amount of the monocrystalline silicon in the cooling step can be further reduced, so that the part of the straight body of the monocrystalline silicon whose residence time in the temperature range of 570 degrees C.±70 degrees C. is in a range from 10 minutes to 50 minutes can be enlarged.

“In order to pull up the monocrystalline silicon with the power of the heating unit being reduced to a half or less of the power of the heating unit immediately before starting the cooling step,” the power of the heating unit may be reduced to half or less of the power of the heating unit immediately before starting the cooling step at a timing: before the monocrystalline silicon is separated from the dopant-added melt; simultaneously with separating the monocrystalline silicon from the dopant-added melt; or after the monocrystalline silicon is separated from the dopant-added melt.

A production method of an epitaxial silicon wafer according to still another aspect of the invention includes: a wafer-slicing step for slicing the monocrystalline silicon produced according to the production method of a monocrystalline silicon to produce a silicon wafer; a hydrogen baking step for heating the silicon wafer in a hydrogen atmosphere; and an epitaxial-film formation step for forming an epitaxial film on the silicon wafer.

The production method of an epitaxial silicon wafer according to the above aspect of the invention preferably includes an argon-annealing step for applying a heat treatment on the silicon wafer prior to the hydrogen baking step, the heat treatment being performed in an argon gas atmosphere at 1200 degrees C. or more and 1220 degrees C. or less for 60 minutes or more and 120 minutes or less.

According to the above arrangement, clusters (micro-precipitates) of oxygen and red phosphorus (cause of development of micropits) can be formed into a solution by being subjected to a solution treatment in the argon-annealing step, so that a high-quality epitaxial silicon wafer whose LPD density is less than 0.3 per square centimeters can be produced.

A monocrystalline silicon according to a further aspect of the invention includes red phosphorus, electrical resistivity of the monocrystalline silicon being 0.5 mΩ·cm or more and less than 0.7 mΩ·cm. The monocrystalline silicon includes a straight body including a crystalline region, a silicon wafer sliced from the crystalline region of the straight body having an LPD density of 90 nm or more of 2.5 per square centimeters or less on a surface of the silicon wafer, the LPD density being measured after applying a heat treatment in a hydrogen atmosphere at 1200 degrees C. for 30 seconds.

An epitaxial silicon wafer according to still further aspect of the invention includes: a silicon wafer sliced from the crystalline region in the straight body of the monocrystalline silicon according to the above aspect of the invention; and an epitaxial film provided on the silicon wafer. The LPD density on a surface of the epitaxial film is 2.5 per square centimeters or less.

Another epitaxial silicon wafer according to still further aspect of the invention includes: a silicon wafer sliced from the crystalline region in the straight body of the monocrystalline silicon according to the above aspect of the invention; and an epitaxial film provided on the silicon wafer. The LPD density on a surface of the epitaxial film is 0.3 per square centimeters or less.

### BRIEF DESCRIPTION OF DRAWING(S)

FIG. 1 is a graph showing a relationship between a time elapsed from the start of cooling and a crystal pull-up height from the start of cooling, which is obtained as a result of Experiment 1 for deriving a producing condition of a monocrystalline silicon according to the invention.

FIG. 2 is a graph showing a relationship between a solidification rate and a residence time in a range of 570 degrees C.±70 degrees C. in the Experiment 1.

FIG. 3 is a graph showing results in a range with 50% or more solidification rate in FIG. 2 in an enlarged manner.

FIG. 4 is a graph showing a relationship between an electrical resistivity of an epitaxial silicon wafer and an LPD density, which is obtained as a result of Experiment 2 for deriving a producing condition of the monocrystalline silicon.

FIG. 5 schematically shows an arrangement of a monocrystal pull-up apparatus according to an exemplary embodiment of the invention.

FIG. 6 schematically shows a production method of monocrystalline silicon by a multi-drawing method according to a modification of the invention.

FIG. 7 schematically shows a production method of monocrystalline silicon by a single-charge pull-up method according to another modification of the invention.

FIG. 8 is a graph showing a relationship between the solidification rate and a temperature at the center of the monocrystalline silicon, which shows an effect of providing a heater (afterheater) according to still another modification of the invention.

FIG. 9 is a graph showing a relationship between the solidification rate and a residence time in the range of 570 degrees C.±70 degrees C., which shows the effect of providing the heater (afterheater) according to the still another modification.

### DESCRIPTION OF EMBODIMENT(S)

### Background of Reaching the Invention

### Experiment 1: Study on Relationship Between Conditions in Cooling Step, and Residence Time in 570 Degrees C.±70 Degrees C. And Development of LPD

In producing a monocrystalline silicon by Czochralski (CZ) process, a monocrystal-formation step for pulling up a monocrystalline silicon, and a cooling step for cooling the monocrystalline silicon are conducted. The monocrystal-formation step includes: forming a shoulder that is continuous with a seed crystal and has a gradually increasing diameter (shoulder-formation step); forming a straight body that is continuous with the shoulder and has a substantially constant diameter (straight-body-formation step); and forming a tail that is continuous with a lower end of the straight body and has a diameter gradually reducing to zero (tail-formation step).

After completing the tail-formation step, a cooling step is conducted and the monocrystalline silicon is taken out of the monocrystal pull-up apparatus.

It is believed that the residence time of the monocrystalline silicon produced as described above in the range of 570 degrees C.±70 degrees C. is reduced toward the lower end of the monocrystalline silicon (i.e. with an increase in the solidification rate) because a cooling time after the monocrystalline silicon is pulled out of the dopant-added melt is reduced (and thus rapidly cooled) toward the lower end.

It should be noted that the solidification rate at an upper end of shoulder is 0% in the description below.

The inventors have conducted a study on whether the development of SF can be further restrained by reducing the residence time in the range of 570 degrees C.±70 degrees C. for a monocrystalline silicon with the electrical resistivity of 0.5 mΩ·cm or more and less than 0.7 mΩ·cm.

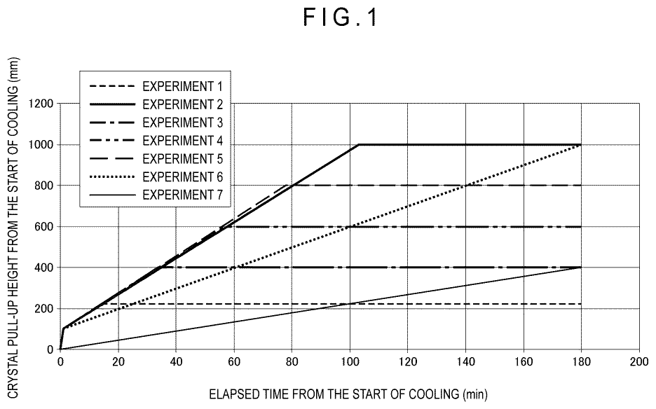

Initially, a monocrystalline silicon was prepared in Experiment 1 to examine the residence time in the range of 570 degrees C.±70 degrees C. for each of the solidification rates. At this time, after the above-described monocrystal-formation step, the heating unit for heating a crucible was turned off immediately after the tail was separated from the dopant-added melt. In the cooling step, the monocrystalline silicon was pulled up according to conditions shown FIG. 1. The “start of cooling” in FIG. 1 indicating the start of the cooling step refers to a time when the “monocrystalline silicon is separated from the dopant-added melt.” The “crystal pull-up height” refers to a “pull-up height after the monocrystalline silicon is separated from the dopant-added melt.”

In Experiment 1, the monocrystalline silicon was pulled up by 100 mm in one minute from the start of cooling and was pulled up at a constant speed to a 220 mm point from the dopant-added melt surface in the subsequent 14 minutes. After being left still, the monocrystalline silicon was taken out of the monocrystal pull-up apparatus after the elapse of 180 minutes from the start of cooling.

A monocrystalline silicon was prepared in Experiment 2 according to conditions shown in FIG. 1 to examine the residence time in the range of 570 degrees C.±70 degrees C. for each of the solidification rates. In Experiment 2, the monocrystalline silicon was pulled-up under the same conditions as in Experiment 1 until one minute from the start of cooling and was pulled up at a constant speed to a 1000 mm point from the dopant-added melt surface in the subsequent 102 minutes. Then, after being left still until an elapse of 180 minutes from the start of cooling, the monocrystalline silicon was taken out of the monocrystal pull-up apparatus.

In Experiments 1 and 2, the dopant-added melt was prepared by adding a dopant (red phosphorus) in a silicon melt so that the electrical resistivity of the silicon wafer was 0.5 mΩ·cm or more and less than 0.7 mΩ·cm. A charge quantity of the dopant-added melt was 100 kg. A diameter of the monocrystalline silicon was 210 mm.

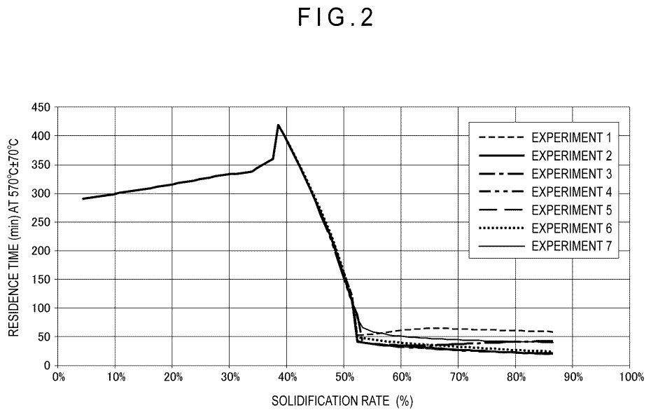

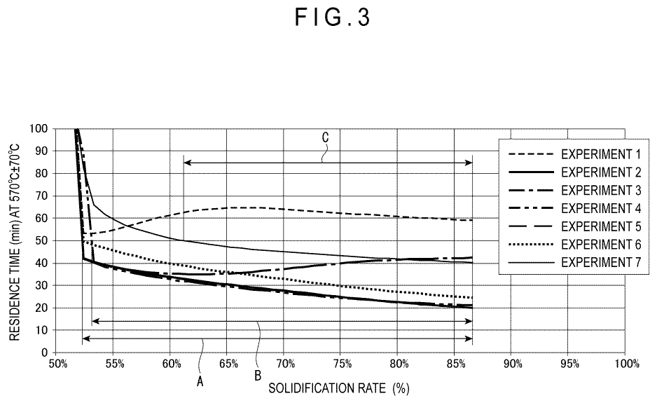

The residence time in the range of 570 degrees C.±70 degrees C. in each of Experiment 1 and Experiment 2 is shown in FIGS. 2 and 3. The residence time in the range from 570 degrees C.±70 degrees C. in a region A shown in FIG. 3, where the solidification rate was approximately in a range from 52% to 87%, was more than 50 minutes in Experiment 1 and was 50 minutes or less in Experiment 2.

Subsequently, 10 silicon wafers of 200 mm diameter each corresponding to a plurality of solidification rates were sliced from the region A as shown in FIG. 3 whose solidification rate was approximately in a range from 52% to 87% in the monocrystalline silicon of Experiments 1 and 2. The sliced silicon wafers were subjected to hydrogen baking step applied prior to forming an epitaxial film and LPD formed thereon was evaluated. In the hydrogen baking step, the silicon wafers were heated for 30 seconds in a hydrogen atmosphere at 1200 degrees C. The number of LPD of a size of 90 nm or more was measured by SP-1 manufactured by KLA-Tencor Corporation in DCN mode.

TABLE 1

| | Experi- | | | | | | |
|---|---|---|---|---|---|---|---|
| | ment 1 | Experiment 2 | Experiment 3 | Experiment 4 | Experiment 5 | Experiment 6 | Experiment 7 |
| Maximum crystal pull- | 220 | 1000 | 400 | 600 | 800 | 1000 | 400 |
| up height (mm) | | | | | | | |
| Time required to reach | 15 | 103 | 34 | 57 | 78 | 180 | 180 |
| maximum crystal pull- | | | | | | | |
| up height (min.) | | | | | | | |
| Average LPD number | 10000 | 146 | 663 | 293 | 201 | 160 | 764 |
| (LPD/wafer) | | | | | | | |
| Average LPD density | 31.52 | 0.46 | 2.09 | 0.92 | 0.63 | 0.50 | 2.41 |
| (LPD/cm²) | | | | | | | |

As shown in Table 1, it is found that the average LPD number and average LPD density were smaller in Experiment 2 than in Experiment 1. Especially, the average LPD density, which was 31.52 per square centimeters in Experiment 1 and was 0.46 per square centimeters in Experiment 2, shows that the development of LPD is further reduced under the conditions of Experiment 2.

As disclosed in Patent Literature 1, micropits developed after the hydrogen baking step can be measured as the LPD of the size of 90 nm or more by SP-1 manufactured by KLA-Tencor Corporation in DCN mode. Thus, it is believed that the density of micropits in a silicon wafer obtained from the monocrystalline silicon in Experiment 2 after hydrogen baking step is 0.46 per square centimeters.

In order to examine allowable conditions in the cooling step, pieces of monocrystalline silicon were prepared in Experiments 3 to 7 according to conditions shown in FIG. 1 to examine the residence time in the range of 570 degrees C.±70 degrees C. for each of the solidification rates. It should be noted that a dopant (red phosphorus) was added in a silicon melt so that the electrical resistivity of the silicon wafer was 0.5 mΩ·cm or more and less than 0.7 mΩ·cm.

Experiments 3 to 6 were conducted under the same conditions as in Experiment 1 until one minute from the start of cooling.

In Experiment 3, the monocrystalline silicon was pulled up at a constant speed from the dopant-added melt surface to 400 mm above the dopant-added melt surface in 33 minutes after one minute from the start of cooling, which was left still until an elapse of 180 minutes from the start of cooling, and was then taken out of the monocrystal pull-up apparatus.

In Experiment 4, the monocrystalline silicon was pulled up at a constant speed from the dopant-added melt surface to 600 mm above the dopant-added melt surface in 56 minutes after one minute from the start of cooling, which was left still until an elapse of 180 minutes from the start of cooling, and was then taken out of the monocrystal pull-up apparatus.

In Experiment 5, the monocrystalline silicon was pulled up at a constant speed from the dopant-added melt surface to 800 mm above the dopant-added melt surface in 77 minutes after one minute from the start of cooling, which was left still until an elapse of 180 minutes from the start of cooling, and was then taken out of the monocrystal pull-up apparatus.

In Experiment 6, the monocrystalline silicon was pulled up at a constant speed from the dopant-added melt surface to 1000 mm above the dopant-added melt surface in 179 minutes after one minute from the start of cooling, and was then taken out of the monocrystal pull-up apparatus.

In Experiment 7, the monocrystalline silicon was pulled up at a constant speed from the dopant-added melt surface to 400 mm above the dopant-added melt surface in 180 minutes from the start of cooling, and was then taken out of the monocrystal pull-up apparatus.

The residence time in the range from 570 degrees C.±70 degrees C. in the region A shown in FIG. 3, where the solidification rate was approximately in a range from 52% to 87%, was 50 minutes or less in Experiments 3, 5, and 6. In Experiment 4, the residence time in the range from 570 degrees C.±70 degrees C. was 50 minutes or less in a region B, where the solidification rate was approximately in a range from 53% to 87%. In Experiment 7, the residence time in the range from 570 degrees C.±70 degrees C. was 50 minutes or less in a region C, where the solidification rate was approximately in a range from 62% to 87%.

From the above, it is found that the residence time of for a temperature of at least a part of a straight body of a monocrystalline silicon to be 570 degrees C.±70 degrees C. can be set in a range of 50 minutes or less by pulling up the monocrystalline silicon by 400 mm or more within 180 minutes after separating the monocrystalline silicon from the dopant-added melt in the cooling step.

Subsequently, 10 silicon wafers each corresponding to a plurality of solidification rates were sliced from the respective parts whose residence time in the range from 570 degrees C.±70 degrees C. was 50 minutes or less in the monocrystalline silicon of Experiments 3 to 7. The sliced silicon wafers were subjected to hydrogen baking step as in Experiment 2 and LPD formed thereon was evaluated.

As shown in Table 1, it was found that the average LPD number and average LPD density were smaller in Experiments 3 to 7 than in Experiment 1 and the average LPD densities in Experiments 3 to 7 were each 2.5 per square centimeters or less.

From the above, it is found that, in producing a monocrystalline silicon containing red phosphorus and having electrical resistivity of 0.5 mΩ·cm or more and less than 0.7 mΩ·cm, at least a part of a straight body of a monocrystalline silicon is rapidly cooled by pulling up the monocrystalline silicon so that the residence time for the temperature of the part of the straight body of the monocrystalline silicon to be 570 degrees C.±70 degrees C. is 50 minutes or less, thus reducing the LPD density to 2.5 per square centimeters or less when a silicon wafer obtained from the rapidly cooled region is subjected to a heat treatment similar to the hydrogen baking step.

### Experiment 2: Study on Relationship Between Presence/Absence of Argon-Annealing Step and Development of LPD

A monocrystalline silicon produced under the same conditions as in Experiment 1 (residence time in the range of 570 degrees C.±70 degrees C. exceeding 50 minutes (no rapid cooling)) was prepared, and a plurality of silicon wafers were sliced from the region A in FIG. 3. Then, using approximately a half of the silicon wafers sliced as described above, the epitaxial silicon wafers of Experiment 8 were produced under the conditions shown in Table 2 below, and epitaxial silicon wafers of Experiment 9 were produced using the remaining approximately half of the silicon wafers.

In Experiment 8, the silicon wafers were subjected to the hydrogen baking step and epitaxial-film formation step. The hydrogen baking step was conducted under the same conditions as in Experiment 1. The epitaxial-film formation step was conducted under the conditions below.

### Epitaxial Film Formation Conditions

Dopant gas: phosphine (PH₃) gas
Material source gas: trichlorosilane (SiHCl₃) gas
Carrier gas: hydrogen gas
Growth temperature: 1080 degrees C.
Thickness of epitaxial film: 3 μm
Electrical resistivity of epitaxial film: 1 Ω·cm

Experiment 9 was conducted in the same manner as in Experiment 8 except that an argon-annealing step was conducted under the conditions below prior to the hydrogen baking step.

### Argon-Annealing Conditions

Atmosphere: argon gas
Heat treatment temperature: 1200 degrees C.
Heat treatment time: 60 minutes

A monocrystalline silicon produced under the same conditions as in Experiment 2 (residence time in the range of 570 degrees C.±70 degrees C. being 50 minutes or less (rapid cooling)) was prepared, and a plurality of silicon wafers were sliced from the region A in FIG. 3. Then, using approximately a half of the silicon wafers sliced as described above, the epitaxial silicon wafers of Experiment 10 were produced, and epitaxial silicon wafers of Experiment 11 were produced using the remaining approximately half of the silicon wafers.

The same steps as in Experiment 8 were conducted in Experiment 10. The same steps as in Experiment 9 were conducted in Experiment 11.

TABLE 2

| | Experiment | Experiment | Experiment | Experiment |
|---|---|---|---|---|
| | 8 | 9 | 10 | 11 |
| Residence time | T > 50 min. | T > 50 min. | T ≤ 50 min. | T ≤ 50 min. |
| (T) in 570° | (no rapid | (no rapid | (rapid | (rapid |
| C. ± 70° C. | cooling) | cooling) | cooling) | cooling) |
| Argon- | No | Yes | No | Yes |
| annealing | | | | |
| step | | | | |

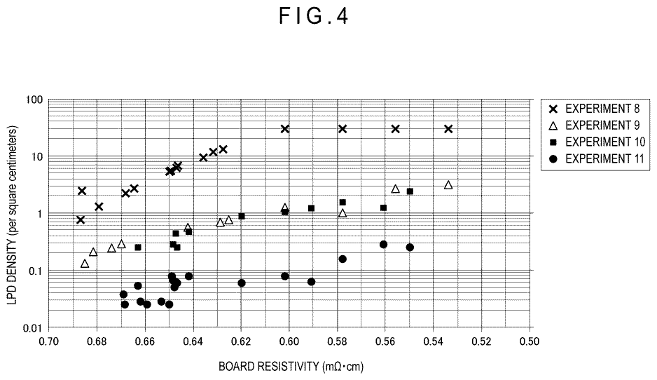

The developments of LPD on epitaxial film surfaces of the epitaxial silicon wafers in Experiments 8 to 11 were evaluated in the same manner as in Experiment 1. The results are shown in FIG. 4. One sample of the silicon wafers was measured for each of the values of electrical resistivity in Experiments 8 to 11 shown in FIG. 4.

As shown in FIG. 4, samples with lower electrical resistivity have larger LPD density in all of Experiments 8 to 11.

The maximum LPD density in each of Experiments 8 to 11 was approximately 30 per square centimeters in Experiment 8, 3 per square centimeters in Experiment 9, 2.5 per square centimeters in Experiment 10, and 0.3 per square centimeters in Experiment 11. It is thus found that the LPD density of an epitaxial film surface of an epitaxial silicon wafer can be reduced to 2.5 per square centimeters or less with the residence time in the range of 570 degrees C.±70 degrees C. to 50 minutes or less in the cooling step. It is further found that the LPD density on an epitaxial film surface of an epitaxial silicon wafer can be reduced to 0.3 per square centimeters by applying an argon-annealing treatment.

Additionally, it is found that, even when the residence time in the range of 570 degrees C.±70 degrees C. exceeds 50 minutes, the LPD density can be made substantially equal to that in Experiment 10 by applying the argon-annealing treatment as in Experiment 9. It should be noted that an epitaxial silicon wafer with reduced LPD density can be produced in Experiment 10 in a simple process for the omission of the argon-annealing treatment.

### Exemplary Embodiment(s)

An Exemplary embodiment of the invention will be described below with reference to the attached drawings.

### Arrangement of Monocrystal Pull-Up Apparatus

Initially, the arrangement of the monocrystal pull-up apparatus will be described.

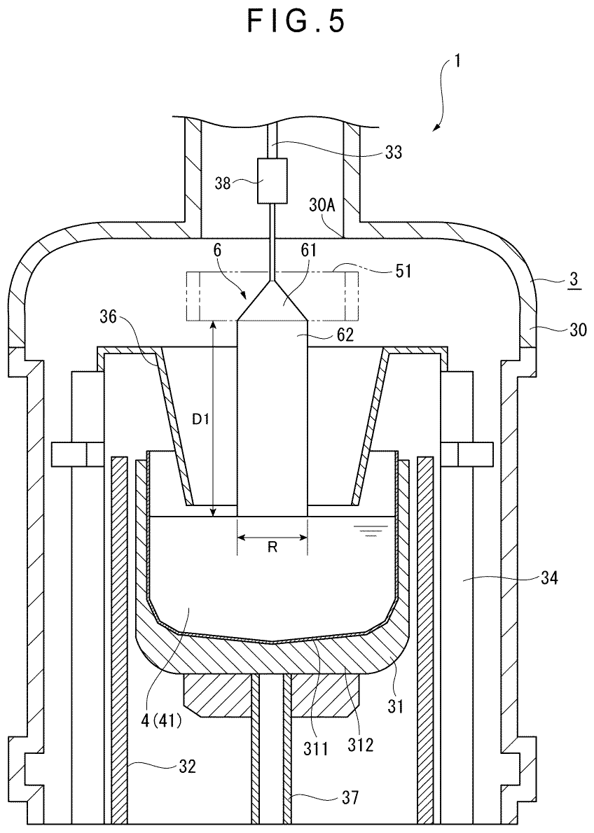

The monocrystal pull-up apparatus 1, which is an apparatus usable for the CZ process, includes a pull-up apparatus body 3 as shown in FIG. 5, a doping device (not shown), and a controller (not shown).

The pull-up apparatus body 3 includes a chamber 30, a crucible 31 located within the chamber 30, a heating unit 32 configured to radiate heat to heat the crucible 31, a pull-up cable 33 (pull-up unit), a heat insulating cylinder 34, and a shield 36.

Inert gas (e.g. Ar gas) is introduced downward from above at a predetermined gas flow rate into the chamber 30 through an intake 30A at an upper part of the chamber 30 under the control of the controller. A pressure (furnace pressure) inside the chamber 30 is to be controlled by the controller.

The crucible 31 is configured to melt polycrystalline silicon (i.e. a material of a silicon wafer) to provide a silicon melt 4. The crucible 31 includes a cylindrical quartz crucible 311 with a closed bottom and a graphite crucible 312 that is disposed outside the quartz crucible 311 to receive the quartz crucible 311. The crucible 31 is supported by a support shaft 37 rotatable at a predetermined speed.

The heating unit 32 is located outside the crucible 31 to heat the crucible 31 so that the polycrystalline silicon inside the crucible 31 melts.

The pull-up cable 33 has a first end connected to a pull-up driver (not shown) located, for instance, above the crucible 31. A seed holder 38 for holding a seed crystal or a doping device (not shown) is attached to a second end of the pull-up cable 33 as desired by a user. The pull-up cable 33 is rotatable in accordance with a drive of the pull-up driver. The pull-up cable 33 is pulled up at a predetermined speed by the pull-up driver controlled by the controller.

The heat insulating cylinder 34 is disposed to surround the crucible 31 and the heating unit 32.

The shield 36 is a heat shield configured to block radiant heat radiated upward from the heating unit 32. The shield 36 is disposed over the surface of the silicon melt 4. The shield 36 is a conical component having openings at upper and lower ends, the opening at the lower end being smaller than the opening at the upper end.

The doping device is configured to volatilize red phosphorus (a solid volatile dopant) to dope the silicon melt 4 in the crucible 31 with red phosphorus. In other words, the doping device is configured to dope the silicon melt 4 with red phosphorus (volatile dopant) to generate a dopant-added melt 41. The doping device is exemplarily configured to dip a lower end portion of a cylindrical portion in the silicon melt 4 to add red phosphorus in the silicon melt 4. Alternatively, the doping device is exemplarily configured to spray volatilized red phosphorus onto the silicon melt 4 with a lower end portion of a cylindrical portion being spaced from the silicon melt 4 to add red phosphorus in the silicon melt 4.

The controller is configured to control a gas flow rate inside the chamber 30, the furnace pressure, and a pull-up speed of the pull-up cable 33 based on an operator's input to control the production of the monocrystalline silicon 6.

### Production Method of Monocrystalline Silicon

Next, an example of a production method of the monocrystalline silicon 6 of 210 mm diameter with use of the monocrystal pull-up apparatus 1 will be described.

The monocrystal pull-up apparatus 1 is configured to heat and melt a polysilicon material under the control of the controller. Subsequently, the monocrystal pull-up apparatus 1 adjusts a gas flow rate and furnace pressure in the chamber 30 to predetermined conditions under the control of the controller and adds red phosphorus (volatile dopant) in the silicon melt 4 to form the dopant-added melt 41.

In order to reduce misfit dislocations in the epitaxial silicon wafer, germanium may be added as well as red phosphorus. The red phosphorus is added in an amount so that electrical resistivity of silicon wafer sliced from the monocrystalline silicon 6 falls in a range of 0.5 mΩ·cm or more and less than 0.7 mΩ·cm.

Subsequently, the controller of the monocrystal pull-up apparatus 1 dips the seed crystal in the melt in accordance with an input by an operator. The controller of the monocrystal pull-up apparatus 1 then pulls up the seed crystal at a predetermined pull-up speed to produce the monocrystalline silicon 6 of a typical size (e.g. 60 kg or more and 180 kg or less).

In the process of pulling-up the seed crystal to produce the monocrystalline silicon 6, the controller conducts: a monocrystal-formation step including a neck-formation step, a shoulder-formation step for forming a shoulder 61, a straight-body-formation step for forming a straight body 62, and a tail-formation step; and a cooling step. In the cooling step, the monocrystalline silicon 6 is pulled up by 400 mm or more within 180 minutes from the timing of separation of the tail from the dopant-added melt 41. The monocrystalline silicon 6 may be pulled up in the cooling step under the same control as in any one of Experiments 2 to 7 as described above, or may be pulled up so that lifting rate draws a curved or stepwise profile. It is preferable that, immediately after the tail is separated from the dopant-added melt 41 (immediately after the start of the cooling step), a power of heating unit 32 is reduced to half or less of the power of the heating unit 32 immediately before the tail is separated from the dopant-added melt 41, more preferably to 0% (i.e. power off the heating unit 32).

The above-described conditions for the cooling step are determined so that the time for the temperature of at least a part of the straight body 62 of the monocrystalline silicon 6 to be 570 degrees C.±70 degrees C. becomes in a range from 10 minutes to 50 minutes. For instance, the residence time in 570 degrees C.±70 degrees C. under each of the conditions in Experiments 2 to 7 is represented as shown in FIG. 2.

While the pieces of monocrystalline silicon 6 except for last-produced monocrystalline silicon 6 are cooled before being taken out (i.e. in the cooling step), the furnace pressure is preferably adjusted to be 13.3 kPa (100 torr) or more and 60 kPa (450 torr) or less. When the furnace pressure is less than 13.3 kPa, the red phosphorus (volatile dopant) is evaporated to increase the electrical resistivity of the monocrystalline silicon 6 to be produced next. Meanwhile, when the furnace pressure exceeds 60 kPa, evaporant is likely to be adhered to an interior of the chamber 30 to inhibit single crystallization of the monocrystalline silicon 6.

The electrical resistivity of a silicon wafer obtained from a region, which is dwelt in the temperature of 570 degrees C.±70 degrees C. for in a range from 10 minutes to 50 minutes, of the monocrystalline silicon 6 produced as described above is 0.5 mΩ·cm or more and less than 0.7 mΩ·cm. An oxygen concentration of the silicon wafer is in a range from 4×10¹⁷ to 10×10¹⁷ atoms/cm³ according to IGFA (Inert Gas Fusion Analysis). The concentration of red phosphorus is in a range from 1.1×10²⁰ to 1.7×10²⁰ atoms/cm³. The concentration of germanium is in a range from 3.0×10¹⁹ to 3.0×10²⁰ atoms/cm³.

When the silicon wafer is heated in a hydrogen atmosphere at 1200 degrees C. for 30 seconds or more, the density of 90 nm or more LPD on the surface of the silicon wafer, which is measured by SP-1 manufactured by KLA-Tencor Corporation in DCN mode and derived from SF, is 2.5 per square centimeters or less. In other words, the density of pits generated on the surface of the silicon wafer is 2.5 per square centimeters or less.

### Production Method of Epitaxial Silicon Wafer

Next, a method of producing an epitaxial silicon wafer (not shown) from the monocrystalline silicon 6 produced according to the above-described production method will be described below.

Initially, after a silicon wafer is sliced from the monocrystalline silicon 6 (wafer-slicing step), the silicon wafer is subjected to a hydrogen baking treatment in order to anneal out oxygen from a surface layer of the thus sliced silicon wafer (hydrogen baking step).

The hydrogen baking treatment is applied in a hydrogen atmosphere at a temperature ranging from 1150 to 1200 degrees C. for a treatment time of 30 seconds or more (e.g. 30 seconds at the shortest).

After the hydrogen baking treatment, an epitaxial film is formed on the silicon wafer using CVD (Chemical Vapor Deposition) process (epitaxial-film formation step). The process temperature for the epitaxial growth ranges from 1000 degrees C. to 1150 degrees C., preferably from 1050 degrees C. to 1080 degrees C.

The silicon wafer before being subjected to the hydrogen baking step is preferably subjected to an argon-annealing treatment (argon-annealing step). The argon-annealing treatment is applied in an argon gas atmosphere at a temperature ranging from 1200 to 1220 degrees C. for a treatment time of 60 minutes or more and 120 minutes or less.

Through the above-described production process, an epitaxial silicon wafer with extremely low electrical resistivity of 0.5 mΩ·cm or more and less than 0.7 mΩ·cm, extremely small number of misfit dislocations in the epitaxial film, and small LPD density of 2.5 per square centimeters on the epitaxial film surface derived from SF can be produced. The epitaxial silicon wafer is sufficiently practical for use in power MOS transistors.

Especially, the LPD density on the epitaxial film surface can be further reduced to 0.3 per square centimeters by applying the argon-annealing treatment.

The above-described high-quality epitaxial silicon wafer with extremely low silicon wafer electrical resistivity and extremely small number of LPD derived from SF cannot be produced by a typical production method and thus is novel and producible only through the production method according to the above-described invention.

### Modification(s)

The scope of the invention is not limited to the above exemplary embodiment but may include, for instance, a variety of improvements and design changes as long as an object of the invention can be achieved.

For instance, in some embodiments, the power of the heating unit 32 is reduced to a half or less of the power of the heating unit 32 immediately before starting the cooling step simultaneously with the separation of the tail from the dopant-added melt 41, or at any timing after the tail is separated from the dopant-added melt 41 and before the monocrystalline silicon 6 is pulled up by 400 mm. The above arrangement also can reduce the heat amount of the monocrystalline silicon 6 in the cooling step as compared with an instance without changing the power of the heating unit 32, thus widening the region whose residence time in the range of 570 degrees C.±70 degrees C. is in a range from 10 minutes to 50 minutes.

The power of the heating unit 32 is reduced to a half of the power of the heating unit 32 immediately before starting the cooling step at a timing before the tail is separated from the dopant-added melt 41 in some embodiments. In this case, the time after the heating unit 32 is powered down and before the tail is separated from the dopant-added melt 41 is preferably 10 minutes or less. This is because, when the time after the heating unit 32 is powered down and before the tail is separated from the dopant-added melt 41 exceeds 10 minutes, the temperature of the dopant-added melt 41 is lowered, so that unnecessary silicon solidified on the surface of the melt may be adhered on the tail.

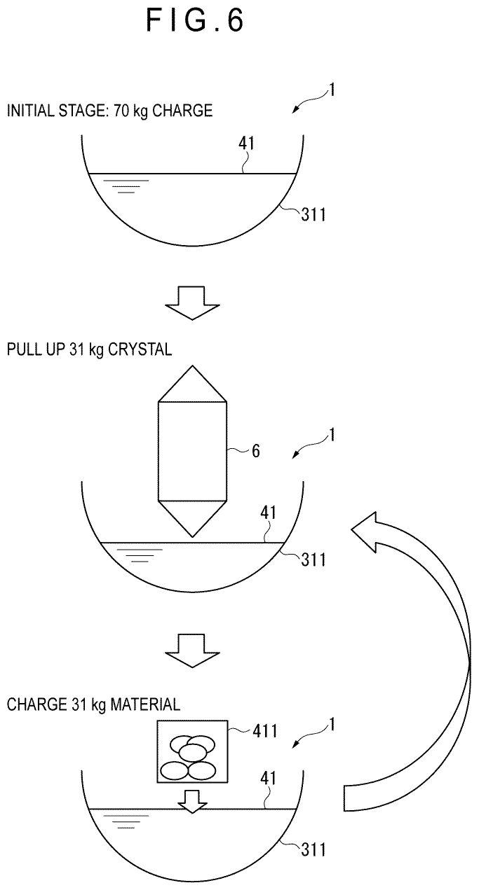

The monocrystalline silicon 6 is produced in some embodiments through a so-called multi-drawing method as shown in FIG. 6, where a plurality of pieces of monocrystalline silicon 6 are pulled up from the single quartz crucible 311, while polysilicon material 411 being charged in the quartz crucible 311 each time one of the plurality of pieces of monocrystalline silicon 6 is pulled up.

At this time, red phosphorus (volatile dopant) is added to 70 kg polysilicon material to prepare the dopant-added melt 41 before pulling up the monocrystalline silicon 6.

During the above pulling-up process, the controller shortens the pull-up time at least in the straight-body-formation step among the formation steps of the monocrystalline silicon 6 (i.e. the neck-formation step, the shoulder-formation step, the straight-body-formation step, and the tail-formation step) as compared with the pull-up time in the exemplary embodiments, thereby producing the monocrystalline silicon 6 of 31 kg with a shorter dimension than that in the exemplary embodiment. In the cooling step, the monocrystalline silicon 6 is pulled up by 400 mm or more within 180 minutes from the separation of the tail from the dopant-added melt 41 as in the above-described exemplary embodiment. Under the above conditions, the residence time of the entire monocrystalline silicon 6 in the range of 570 degrees C.±70 degrees C. falls in, for instance, that of the region A of Experiment 2 as shown in FIG. 3.

Specifically, when a monocrystalline silicon of a dimension in the exemplary embodiment is produced, a lower end portion of the monocrystalline silicon (i.e. the portion of Experiment 2 whose solidification rate is greater than 52% in FIG. 2) is heated at a temperature higher than 570 degrees C.±70 degrees C. after completing the tail-formation step to enter the cooling step. It is believed that the lower end portion of the monocrystalline silicon is rapidly cooled from the above state, so that the time dwelt within the range of 570 degrees C.±70 degrees C. becomes short (50 minutes or less). Meanwhile, an upper end portion of the monocrystalline silicon (a portion with the solidification rate of less than 52% in Experiment 2 in FIG. 2) is cooled to a temperature lower than 570 degrees C.±70 degrees C. in entering the cooling step. It is believed that, even when the upper end portion of the monocrystalline silicon is rapidly cooled from the above state, the time for the upper end portion to be dwelt within the range of 570 degrees C.±70 degrees C. becomes longer (more than 50 minutes) than the lower end portion of the monocrystalline silicon. Consequently, it is believed that relatively large number of SF is caused at the upper end portion of the monocrystalline silicon and development of SF is relatively reduced at the lower end portion of the monocrystalline silicon.

In contrast, in the production method shown in FIG. 6, the monocrystalline silicon 6, which has a shorter dimension than that in the above-described exemplary embodiment, is produced, so that the monocrystalline silicon 6 can be heated in the entirety thereof to a temperature higher than the range of 570 degrees C.±70 degrees C. after the tail-formation step is completed and to enter the cooling step. By rapidly cooling the entirety of the monocrystalline silicon 6 from the above state, the time for the monocrystalline silicon 6 to be dwelt within the range of 570 degrees C.±70 degrees C. can be made short as in the region A in Experiments 2, 3, 5 and 6, the region B in Experiment 4, and the region C in Experiment 7 as shown in FIG. 3.

As a result, the time for the temperature of the monocrystalline silicon 6 to be within the range of 570 degrees C.±70 degrees C. becomes in a range from 10 minutes to 50 minutes, so that the development of LPD can be further reduced over the entire length of the monocrystalline silicon.

After one of the pieces of monocrystalline silicon 6 is produced, the monocrystal pull-up apparatus 1 is loaded with a material 411 (silicon, red phosphorus, germanium) for preparing 31 kg dopant-added melt 41 in the quartz crucible 311 to produce the next one of the pieces of monocrystalline silicon 6 of 31 kg.

In the cooling step for the pieces of monocrystalline silicon 6 except for the last monocrystalline silicon 6, it is preferable that the furnace pressure is adjusted to be in a range from 13.3 kPa to 60 kPa. The reason for the furnace pressure to be as described above is the same as that described in the exemplary embodiment.

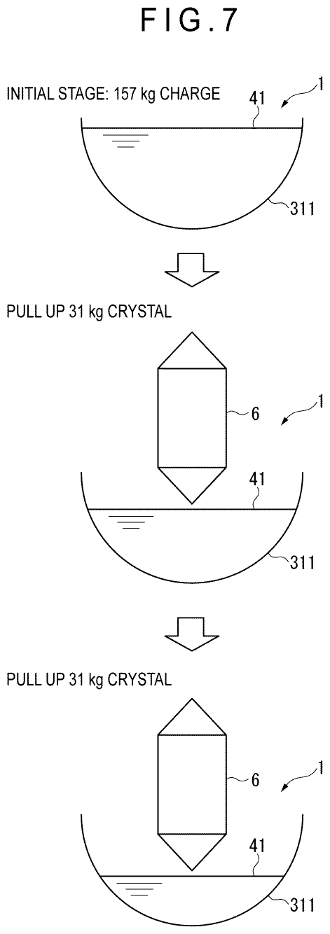

The monocrystalline silicon 6 of the same size as the monocrystalline silicon 6 described in the multi-drawing method is produced in a so-called single-charge pull-up method as shown in FIG. 7 in some embodiments, in which the dopant-added melt 41 for a plurality of pieces of monocrystalline silicon is charged in the single quartz crucible 311 of the monocrystal pull-up apparatus 1 and the plurality of pieces of monocrystalline silicon 6 are pulled up one by one. In the above, the monocrystalline silicon 6 is pulled up by 400 mm or more within 180 minutes from the separation of the tail from the dopant-added melt 41 in the cooling step as in the above-described exemplary embodiment.

When two pieces of monocrystalline silicon 6 are produced, in the cooling step for the second one of the pieces of monocrystalline silicon 6 after the first one of the pieces of monocrystalline silicon 6 is pulled up, it is preferable that the furnace pressure is adjusted to be in a range from 13.3 kPa to 60 kPa. The reason for setting the furnace pressure as described above is the same as that described in the exemplary embodiment.

It should be noted that, the single-charge pull-up method is applicable in the multi-drawing method when the last one of the pieces of monocrystalline silicon is pulled up without adding the material.

For instance, 157 kg dopant-added melt 41 is charged at an initial stage and 31 kg pieces of monocrystalline silicon 6 are pulled up in five consecutive times in some embodiments. The time for the temperature of the monocrystalline silicon 6 to be 570 degrees C.±70 degrees C. can be set in a range from 10 minutes to 50 minutes in the above process.

In the cooling step in the multi-drawing method and single-charge pull-up method, the monocrystalline silicon 6 is pulled up with the power of the heating unit 32 being reduced to half or less of the power of the heating unit immediately before starting the cooling step as in the exemplary embodiment and the above modifications. However, since it is necessary to raise the power of the heating unit 32 prior to produce the next one of the pieces of monocrystalline silicon 6, it is preferable that the monocrystalline silicon 6 is pulled up without powering down the heating unit 32.

An afterheater 51 (heater) is provided as shown in chain double-dashed lines in FIG. 5 in some embodiments. The afterheater 51 is, for instance, a hollow cylindrical component. The afterheater 51 is preferably located at a position where a distance D1 from the surface of the dopant-added melt 41 to a lower end of the afterheater 51 is 1.5 to 3.0 times as large as a diameter R of the monocrystalline silicon 6. When the afterheater 51 is located at a position where the distance D1 is less than 1.5 times as large as the diameter R of the monocrystalline silicon 6, the afterheater 51 is located so close to the surface of the dopant-added melt 41 that a temperature gradient near the solid-liquid interface becomes gentle to possibly develop dislocations due to, for instance, compositional supercooling.

Next, the effect of the afterheater 51 located at the above-descried position will be described.

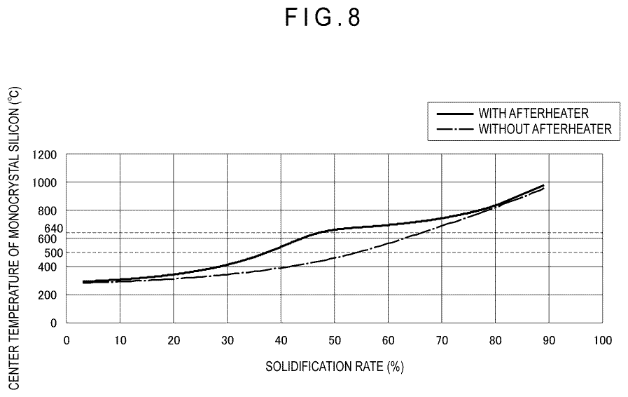

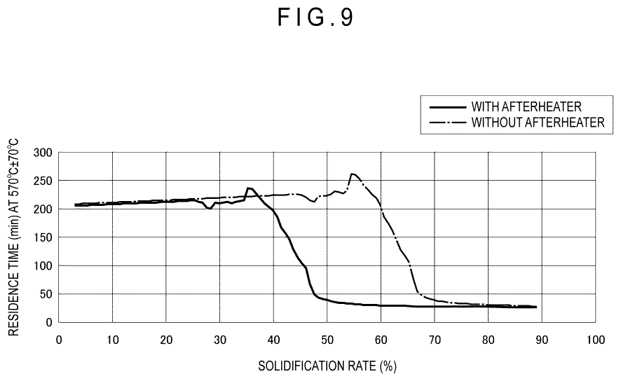

The monocrystalline silicon 6 was produced using the monocrystal pull-up apparatus 1 without the afterheater 51 (e.g. under the same conditions as in Experiment 1). Then, a temperature distribution at the center of the monocrystalline silicon when the tail was separated from the dopant-added melt 41 was examined for each of the solidification rates. The results are shown in a dot-and-dash line in FIG. 8. Further, the residence time in the range of 570 degrees C.±70 degrees C. was examined for each of the solidification rates. The results are shown in a dot-and-dash line in FIG. 9.

The monocrystalline silicon 6 was produced under the same conditions as in Experiment 1 except that the afterheater 51 was located at the position shown by chain double-dashed lines in FIG. 5. Specifically, the monocrystalline silicon 6 was produced while being heated by the afterheater 51 in the straight-body-formation step to reduce the decline in the temperature of the monocrystalline silicon 6. Then, the temperature distribution at the center of the monocrystalline silicon and the residence time in the range of 570 degrees C.±70 degrees C. was examined for each of the solidification rates. The results are shown in a solid line in each of FIGS. 8 and 9.

It is found that, with the presence of the afterheater 51, the period in which the temperature is 640 degrees C. (570 degrees C.±70 degrees C.) or more after the tail-formation step becomes longer than the arrangement without providing the afterheater 51 as shown in FIG. 8. Specifically, the afterheater 51, which was turned on when the straight-body-formation step was performed, was turned off in the cooling step after the tail-formation step, and the monocrystalline silicon 6 was pulled up by 400 mm or more within 180 minutes from the separation of the tail from the dopant-added melt 41 to rapidly cool the part whose temperature was 640 degrees C. or more, as in the exemplary embodiment. As a result, the part of the monocrystalline silicon 6 whose temperature is 570 degrees C.±70 degrees C. for in a range from 10 minutes to 50 minutes, can be increased. In other words, the part with the density of pits generated on the silicon wafer being 2.5 per square centimeters or less can be increased. In fact, it is found that the use of the afterheater 51 significantly increases the part of the monocrystalline silicon 6, whose temperature is 570 degrees C.±70 degrees C. for in a range from 10 minutes to 50 minutes, as shown in FIG. 9.

1. A production method of a monocrystalline silicon, the method comprising:
forming the monocrystalline silicon weighing 60 kg or more and 180 kg or less by contacting a seed crystal with a dopant-added melt contained within a crucible disposed inside a chamber of a monocrystal pull-up apparatus, the dopant-added melt comprising a silicon melt and red phosphorus added to the silicon melt;
after bringing the seed crystal into contact with the dopant-added melt, pulling up the seed crystal with a pull-up unit contained in the monocrystal pull-up apparatus to pull up the monocrystalline silicon; and
cooling the monocrystalline silicon;
the method further comprising:
adding the red phosphorus into the silicon melt so that an electrical resistivity of the monocrystalline silicon falls in a range of 0.5 mΩ·cm or more and less than 0.7 mΩ·cm,
wherein:
during the cooling, the monocrystalline silicon is pulled up a distance of 400 mm or more within 180 minutes after separating a tail of the monocrystalline silicon from the dopant-added melt,
a time for a temperature of a part of a straight body of the monocrystalline silicon to be 570° C.±70° C. is in a range from 10 minutes to 50 minutes, and
the part of the straight body of the monocrystalline silicon is included in a region of the straight body having a solidification percentage in a range from 52% to 87%.

2. The production method according to claim 1, wherein during the cooling, the monocrystalline silicon is pulled up with a power of a heating unit configured to heat the crucible being half or less of the power of the heating unit immediately before starting the cooling the monocrystalline silicon, at a timing of:
before the monocrystalline silicon is separated from the dopant-added melt;
simultaneously with separating the monocrystalline silicon from the dopant-added melt; or
after the monocrystalline silicon is separated from the dopant-added melt.

3. A production method of an epitaxial silicon wafer, comprising:
slicing the monocrystalline silicon produced according to the production method according to claim 1 to produce a silicon wafer;
heating the silicon wafer in a hydrogen atmosphere; and
forming an epitaxial film on the silicon wafer.

4. The production method according to claim 3, further comprising:
applying a heat treatment on the silicon wafer prior to the heating the silicon wafer in a hydrogen atmosphere, the heat treatment being performed in an argon gas atmosphere at 1200° C. or more and 1220° C. or less for 60 minutes or more and 120 minutes or less.

5. The production method according to claim 1, the method further comprising:
locating an afterheater at a position where a distance from a surface of the dopant-added melt to a lower end of the afterheater is 1.5 to 3.0 times as large as a diameter of the monocrystalline silicon,
during formation of the straight-body of the monocrystalline silicon, heating the monocrystalline silicon with the afterheater to reduce a decline in a temperature of the monocrystalline silicon, and
during the cooling of the monocrystalline silicon, turning off the afterheater to stop the heating of the monocrystalline silicon.

6. A monocrystalline silicon comprising red phosphorus, an electrical resistivity of the monocrystalline silicon being 0.5 mΩ·cm or more and less than 0.7 mΩ·cm, wherein the monocrystalline silicon comprises a straight body comprising a crystalline region, a silicon wafer sliced from the crystalline region of the straight body having an LPD density of 90 nm or more of 2.5 per square centimeters or less on a surface of the silicon wafer, the LPD density being measured after applying a heat treatment in a hydrogen atmosphere at 1200° C. for 30 seconds.

7. An epitaxial silicon wafer comprising:
a silicon wafer sliced from the crystalline region in the straight body of the monocrystalline silicon according to claim 6; and
an epitaxial film provided on the silicon wafer,
wherein the LPD density on a surface of the epitaxial film is 2.5 per square centimeters or less.

8. An epitaxial silicon wafer comprising:
a silicon wafer sliced from the crystalline region of the straight body of the monocrystalline silicon according to claim 6; and
an epitaxial film provided on the silicon wafer,
wherein the LPD density on a surface of the epitaxial film is 0.3 per square centimeters or less.
